(19) United States
(12) Patent Application Publication
(10) Pub. No.: US 2023/0131502 A1
(43) Pub. Date: Apr. 27, 2023

(54) SHOWERHEAD THERMAL MANAGEMENT USING GAS COOLING

(71) Applicant: Lam Research Corporation, Fremont, CA (US)

(72) Inventors: Alon Ganany, Tigard, OR (US); Sean Michael Donnelly, Portland, OR (US)

(21) Appl. No.: 17/912,385

(22) PCT Filed: Mar. 16, 2021
(86) PCT No.: PCT/US2021/022638

§ 371 Date: Sep. 16, 2022

Related U.S. Application Data
(60) Provisional application No. 63/010,976, filed on Apr. 16, 2020.

(51) Int. Cl. C23C 16/455; C23C 16/52

(52) U.S. Cl. CPC C23C 16/45572; C23C 16/45565; C23C 16/52

(57) ABSTRACT

A temperature-controlled showerhead assembly includes a stem with cooling gas passageways and at least one process gas delivery passageway, and a back plate thermally coupled to the stem. The showerhead also includes a face plate attached to the back plate and a convective heat transfer element (CHTE) thermally coupled to the back plate. The CHTE includes a sealing cup which isolates the CHTE heat transfer structures from the process environment. The CHTE includes an internal plenum including an inlet path for receiving a flow of cooling gas via at least a first one of the plurality of cooling gas passageways, and an outlet path for removing the flow of cooling gas from the CHTE via at least a second one of the plurality of cooling gas passageways. The received flow of cooling gas is thermally coupled with a surface of the back plate.

### CLAIM OF PRIORITY

This application claims the benefit of priority to U.S. Provisional Patent Application No. 63/010,976, filed on Apr. 16, 2020, which is incorporated by reference herein in its entirety.

### TECHNICAL FIELD

The subject matter disclosed herein generally relates to systems, methods, apparatuses, and machine-readable media storing computer programs for thermal management during semiconductor device fabrication, including thermal management of showerheads (or other parts such as pedestals) using clean dry air (CDA) (or other cooling gases) in connection with a heat exchanger.

### BACKGROUND

Semiconductor device processing apparatuses are used to process semiconductor substrates by techniques including etching, physical vapor deposition (PVD), chemical vapor deposition (CVD), plasma-enhanced chemical vapor deposition (PECVD), metalorganic chemical vapor deposition (MOCVD), atomic layer deposition (ALD), plasma-enhanced atomic layer deposition (PEALD), pulsed deposition layer (PDL), plasma-enhanced pulsed deposition layer (PEPDL), and resist removal. A semiconductor device (e.g., a substrate) may be arranged on a substrate support, such as a pedestal, an electrostatic chuck (ESC), and so forth, in a processing chamber of the semiconductor device processing apparatus. During processing, a gas mixture is introduced into the processing chamber via a showerhead, and plasma may be used to enhance chemical reactions within the processing chamber.

In semiconductor device processing apparatuses, such as CVD-based deposition chambers, the pedestal may be heated and the showerhead may be heated as well as cooled. However, during some stages of a CVD-based process, heat may need to be removed from the showerhead (e.g., during deposition), while during other stages of the CVD-based process there is no need for heat removal (e.g., during conditioning stages). Conventional showerhead cooling techniques include liquid cooling, which is associated with multiple drawbacks. For example, liquid cooling does allow for some modulation of heat removal, but the available depth of modulation is strongly bounded by the allowable temperature range of the coolant. The nature of this limitation varies between coolants. For aqueous coolants, the limitation is primarily due to water's low boiling point, and secondarily due to water's corrosivity. For fluorocarbon, siloxane, and silicate-ester coolants, the limitation is either boiling point or decomposition temperature. Some hydrocarbon and liquid-metal coolants allow deep modulation, but are impractical for other reasons (flammability, toxicity, reactivity, corrosivity). Additionally, fluorocarbon coolants (e.g. Galden) generate extremely toxic products (e.g., hydrogen fluoride) during thermal decomposition, which creates a safety concern. In this regard, inadequate temperature control of ashable hardmask (AHM) showerheads leads to temperature spikes during the plasma deposition step and over-cooling during conditioning leading to throughput loss, substrate defects, and showerhead degradation.

The background description provided herein is for the purposes of generally presenting the context of the disclosure. It should be noted that the information described in this section is presented to provide the skilled artisan some context for the following disclosed subject matter and should not be considered as admitted prior art. More specifically, work of the presently named inventors, to the extent it is described in this background section, as well as aspects of the description that may not otherwise qualify as prior art at the time of filing, are neither expressly nor impliedly admitted as prior art against the present disclosure.

### SUMMARY

Methods, systems, and computer programs are presented for thermal management during semiconductor device fabrication, including thermal management of showerheads (or other parts such as pedestals) using clean dry air (CDA) (or other cooling gases) in connection with a heat exchanger.

A temperature-controlled showerhead assembly includes a stem comprising a plurality of cooling gas passageways and at least one process gas delivery passageway, the at least one process gas delivery passageway entering the stem at a first end and exiting the stem at a second end opposite the first end. The temperature-controlled showerhead assembly further includes a back plate structurally coupled to the stem at the second end, and a face plate thermally coupled to the stem and attached to the back plate, the face plate and the back plate enclose a plenum for distribution of process gasses. The temperature-controlled showerhead assembly further includes a convective heat transfer element (CHTE) thermally coupled to the back plate. The CHTE has an internal plenum including an inlet path for receiving a flow of cooling gas via at least a first one of the plurality of cooling gas passageways, and an outlet path for removing the flow of cooling gas from the CHTE via at least a second one of the plurality of cooling gas passageways. The received flow of cooling gas may be thermally coupled with a surface of the back plate.

Another general aspect includes a temperature control system for controlling showerhead temperature in a semiconductor device processing chamber. The temperature control system includes a semiconductor device processing chamber comprising a temperature-controlled showerhead. The showerhead includes a stem comprising a plurality of cooling gas passageways and at least one process gas delivery passageway. The at least one process gas delivery passageway enters the stem at a first end and exits the stem at a second end opposite the first end. The showerhead includes a back plate structurally coupled to the stem at the second end, and a face plate thermally coupled to the stem and attached to the back plate. The face plate and the back plate define a plenum therebetween. The showerhead further includes at least one temperature sensor thermally coupled to the back plate and configured to measure a temperature of at least one surface area of the back plate. The showerhead further includes a convective heat transfer element (CHTE) thermally coupled to the stem and the back plate. The CHTE includes an internal plenum including an inlet path for receiving a flow of cooling gas via at least a first one of the plurality of cooling gas passageways, and an outlet path for removing the flow of cooling gas from the CHTE via at least a second one of the plurality of cooling gas passageways. The received flow of cooling gas may be thermally coupled with a surface of the back plate. The temperature control system further includes a controller coupled to the plurality of cooling gas passageways and the at least one temperature sensor of the showerhead. The controller is configured to set a flow rate of the flow of cooling gas through the inlet path of the CHTE based on the measured temperature.

Another general aspect includes a temperature control system for controlling showerhead temperature in a semiconductor device processing chamber. The system includes a semiconductor device processing chamber comprising a temperature-controlled showerhead. The showerhead includes a stem comprising a plurality of cooling gas passageways and at least one process gas delivery passageway. The at least one process gas delivery passageway enters the stem at a first end and exits the stem at a second end opposite the first end. The showerhead further includes a back plate structurally coupled to the stem at the second end, and a face plate thermally coupled to the stem and attached to the back plate. The face plate and the back plate define a plenum therebetween, the plenum receiving the process gas via the process gas passageway. The showerhead further includes a plurality of temperature sensors thermally coupled to the back plate and configured to measure a plurality of temperatures of a corresponding plurality of heating zones of the back plate. The showerhead further includes a convective heat transfer element (CHTE) thermally coupled to the stem and the back plate. The CHTE includes a plurality of inlet paths configured to receive flows of cooling gas via a first subset of the plurality of cooling gas passageways and a plurality of outlet paths for removing the flows of cooling gas from the CHTE via a second subset of the plurality of cooling gas passageways. The received flows of cooling gas for each of the plurality of inlet paths may be thermally coupled with a corresponding heating zone of the plurality of heating zones of the back plate. The temperature control system further includes a controller coupled to the plurality of cooling gas passageways and the plurality of temperature sensors. The controller is configured to set a flow rate for each of the flows of cooling gas through the plurality of inlet paths of the CHTE based on the measured plurality of temperatures. The temperature control system further includes a cooling system coupled to at least the second subset of the plurality of cooling gas passageways and configured to cool the flows of cooling gas removed from the CHTE.

An additional general aspect includes a method for regulating showerhead temperature using gas cooling. The method includes providing a showerhead including a stem coupled to a back plate, the stem including a plurality of cooling gas passageways and a convective heat transfer element (CHTE) thermally coupled to the back plate. The CHTE includes an inlet path coupled to at least a first one of the plurality of cooling gas passageways, and an outlet path coupled to at least a second one of the plurality of cooling gas passageways. The method further includes measuring a temperature of at least one surface area of the hack plate using at least one temperature sensor thermally coupled to the back plate. The method further includes causing the inlet path to receive a flow of cooling gas via at least the first one of the plurality of cooling gas passageways. The method further includes setting a flow rate of the flow of cooling gas through the inlet path of the CHTE based on the measured temperature.

### BRIEF DESCRIPTION OF THE DRAWINGS

Various ones of the appended drawings merely illustrate example embodiments of the present disclosure and cannot be considered as limiting its scope.

FIG. 1 illustrates a vacuum chamber, such as a deposition chamber, for manufacturing semiconductor devices using deposition techniques and a showerhead with a CHTE, according to some example embodiments.

FIG. 2 illustrates a temperature-controlled showerhead using a CHTE implementing gas cooling techniques discussed herein, according to some embodiments.

FIG. 3 illustrates a diagram of a CHTE implementing gas cooling techniques discussed herein, according to some embodiments.

FIG. 4 is a cross-sectional diagram of a temperature-controlled showerhead using a CHTE implementing gas cooling techniques discussed herein, according to some embodiments.

FIG. 5 is another diagram of a temperature-controlled showerhead using a CHTE implementing gas cooling techniques discussed herein, according to some embodiments.

FIG. 6 is a diagram illustrating a cross-sectional view of inlet and outlet paths of a CHTE implementing gas-based cooling techniques discussed herein, according to some embodiments.

FIG. 7 is a diagram illustrating a cross-sectional view of an inlet path and an outlet path of a CHTE implementing gas-based cooling techniques discussed herein, according to some embodiments.

FIG. 8 is another diagram illustrating a cross-sectional view of an inlet path and an outlet path of a CHTE implementing gas-based cooling techniques discussed herein with the inlet path including flow-impingement devices, according to some embodiments.

FIG. 9A is a diagram of a top view of a temperature-controlled showerhead using a CHTE implementing gas-based cooling techniques associated with multiple inlet and outlet cooling gas passageways, according to some embodiments.

FIG. 9B and FIG. 9C illustrate different configurations of heating zones, which can be used by the temperature-controlled showerhead of FIG. 9A, according to some embodiments.

FIG. 10A and FIG. 10B illustrate different configurations of inlet and outlet cooling gas passageways within a stem of a temperature-controlled showerhead, according to some embodiments.

FIG. 11 illustrates a system for temperature control of a showerhead during semiconductor device fabrication, according to some embodiments.

FIG. 12 is a block diagram of a controller, which can be used to control the rate of flow of cooling gas in the system of FIG. 11, according to some embodiments.

FIG. 13 is a diagram illustrating a cross-sectional view of an inlet path and an outlet path of a CHTE implementing gas cooling techniques discussed herein with the inlet path including multiple nozzles as flow-impingement devices forming different heating zones, according to some embodiments.

FIG. 14A is a graph showing heat flux incident upon the face of a showerhead, according to some embodiments.

FIG. 14B illustrates an array of jet nozzles having an increased spatial frequency of nozzles in an annular zone around mid-radius, to increase the cooling effect in the region of the elevated heat flux illustrated in FIG. 14A, according to some embodiments.

FIG. 15 is a flowchart of a method for controlling etch rate and plasma uniformity using magnetic fields in semiconductor manufacturing equipment, according to some example embodiments.

FIG. 16 is a block diagram illustrating an example of a machine upon which one or more example method embodiments may be implemented, or by which one or more example embodiments may be controlled.

### DETAILED DESCRIPTION

The description that follows includes systems, methods, techniques, instruction sequences, and computing machine program products (e.g., stored on machine-readable media) that embody illustrative embodiments of the present disclosure. In the following description, for purposes of explanation, numerous specific details are set forth in order to provide a thorough understanding of example embodiments directed to thermal management during semiconductor device fabrication, including thermal management of showerheads (or other parts such as pedestals) using clean dry air (CDA) (or other cooling gases) in connection with a heat exchanger. It will be evident, however, to one skilled in the art, that the present embodiments may be practiced without these specific details.

A portion of the disclosure of this patent document contains material that is subject to copyright protection. The copyright owner has no objection to the facsimile reproduction by anyone of the patent document or the patent disclosure, as it appears in the Patent and Trademark Office patent files or records, but otherwise reserves all copyright rights whatsoever. The following notice applies to any data as described below and in the drawings that form a part of this document: Copyright Lam Research Corporation, 2020, All Rights Reserved.

To maximize heat removal by a cooling gas (e.g., gas such as CDA) from a hot part used in semiconductor device fabrication (e.g., a showerhead), a convective heat transfer element (CHTE) may be used, where the geometry of the CHTE may be optimized to provide contact surface for heat conduction (e.g., heat flow from the hot part to one or more elements of the CHTE), as well as to provide surface area for heat convection by the gas (e.g., heat flow from the CHTE element to the gas). A CHTE using CDA may provide both extra cooling capacity and fast response. In some aspects, additive manufacturing (AM) may be used for producing an optimized cost-effective CHTE. In this regard, the CHTE will be physically isolated from the process gases by a machined sealing cup. This isolation will neutralize the current AM technology limitations wrt the semiconductor industry requirements, e.g. AM powders compatibility with the industry chemistries; and insufficient surface quality for ultra-high vacuum (UHV) sealing and contamination prevention. Using AM to manufacture the CHTE (not the sealing cup) will allow an advanced tailoring and optimization of performance and cost. New Generative Design tools will push this optimization even further.

In some aspects, the CHTE of a temperature-controlled showerhead may include one or more inlet paths and outlet paths coupled to multiple cooling gas passageways through the showerhead stem. The temperature-controlled showerhead may further include one or more temperature sensors (e.g., in a back plate or a front plate of the showerhead) configured to measure (e.g., periodically) surface temperature associated with one or more heating zones of the showerhead. A mass flow controller (MFC) is configured to control the flow rate in individual inlet and outlet paths in the CHTE based on the measured surface temperature so as to individually control cooling of each of the one or more heating zones. In this regard, the disclosed techniques can be used to achieve thermal modulation through cooling gas (e.g., a gas such as CDA) streaming and throttling via optimally-designed heat transfer structures of a CHTE for gas cooling of parts in a semiconductor device fabrication environment, eliminating the risks and drawbacks associated with using liquid coolants such as water and fluorocarbon-based coolants.

The disclosed CHTE includes a sealing cup which isolates the CHTE heat transfer structures from the process environment (e.g., from the process gases used in the deposition chamber), resulting in full and tight separation between the cooling gas (e.g., CDA) and the process environment as well as protection of the CHTE heat transfer structures from deposition and process gases. In some aspects, the disclosed temperature-controlled showerhead may be 3D printed (AM'ed) with the heat transfer structures of the CHTE built into it.

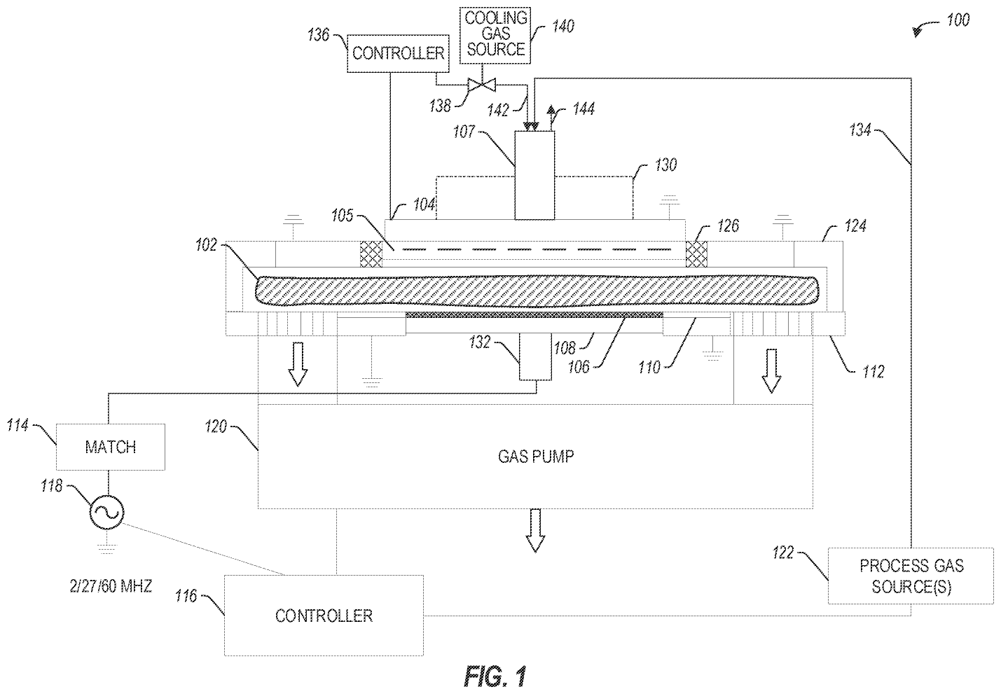

Various techniques and options for configuring thermal management of showerheads (or other parts used in semiconductor device fabrication) using cooling gas (such as CDA) are illustrated in connection with FIG. 1-FIG. 16.

FIG. 1 illustrates a vacuum chamber 100, such as a deposition chamber, for manufacturing semiconductor devices (e.g., substrates) using deposition techniques and a showerhead with a CHTE, according to some example embodiments. Exciting an electric field between two electrodes is one of the methods to obtain radio frequency (RF) gas discharge in a vacuum chamber. When an oscillating voltage is applied between the electrodes, the discharge obtained is referred to as a CCP discharge.

Plasma 102 may be created utilizing stable feedstock gases to obtain a wide variety of chemically reactive by created by the dissociation of the various molecules caused by electron-neutral collisions. The chemical aspect of deposition is based on a capacitive discharge introduced in the process gas from the process gas source 122, resulting in the generation of the plasma 102, changing the gas molecules and generating reactive species of new compounds that are deposited onto the substrate. The chemical aspect of etching involves the reaction of the neutral gas molecules and their dissociated by-products with the molecules of the to-be-etched surface and producing volatile molecules, which can be pumped away. When a plasma is created, the positive ions are accelerated from the plasma across a space-charge sheath separating the plasma from chamber walls to strike the wafer surface with enough energy to remove material from the wafer surface or for densification of deposited film. This is known as ion bombardment or ion sputtering. Some industrial plasmas, however, do not produce ions with enough energy to efficiently etch or densify a surface by purely physical means.

A controller 116 manages the operation of the vacuum chamber 100 by controlling the different elements in the chamber, such as RF generator 118, gas sources 122, and gas pump 120. In one embodiment, fluorocarbon gases, such as CF₄ and C₄F₈, are used in a dielectric etch process for their anisotropic and selective etching capabilities, but the principles described herein can be applied to other plasma-creating gases. The fluorocarbon gases are readily dissociated into chemically reactive by-products that include smaller molecular and atomic radicals. These chemically reactive by-products etch away the dielectric material.

The vacuum chamber 100 illustrates a processing chamber with a top electrode 104 and a bottom electrode 108 as part of a pedestal 132. The top electrode 104 may be grounded or coupled to an RF generator (not shown), and the bottom electrode 108 is coupled to the RF generator 118 via a matching network 114 coupled to the pedestal 132. The RF generator 118 provides RF power in one or multiple (e.g., two or three) different RF frequencies. According to the desired configuration of the vacuum chamber 100 for a particular operation, at least one of the three RF frequencies may be turned on or off. In the embodiment shown in FIG. 1, the RF generator 118 is configured to provide, e.g., 2 MHz, 27 MHz, and 60 MHz frequencies, but other frequencies are also possible.

The vacuum chamber 100 includes a gas showerhead 105 as part of the top electrode 104 to input process gas into the vacuum chamber 100 provided by the gas source(s) 122, and a perforated confinement ring 112 that allows the gas to be pumped out of the vacuum chamber 100 by gas pump 120. In some example embodiments, the gas pump 120 is a turbomolecular pump, but other types of gas pumps may be utilized.

When substrate 106 is present in the vacuum chamber 100 and is supported by pedestal 132, silicon focus ring 110 is situated next to the substrate 106 such that there is a uniform RF field at the bottom surface of the plasma 102 for uniform etching on the surface of the substrate 106. The pedestal 132 typically includes a chuck and lift pins (not illustrated in FIG. 1) to raise and lower the substrate 106 during and between the deposition and/or plasma treatment reactions. The chuck may be an electrostatic chuck, a mechanical chuck, a vacuum chuck or various other types of chucks as available for use in the industry. The embodiment of FIG. 1 shows a triode reactor configuration where the top electrode 104 is surrounded by a symmetric RF ground electrode 124. Insulator 126 is a dielectric that isolates the ground electrode 124 from the top electrode 104. Other implementations of the vacuum chamber 100 are also possible without changing the scope of the disclosed embodiments.

The substrate 106 can include, for example, wafers (e.g., having a diameter of 100 mm, 150 mm, 200 mm, 300 mm, 450 mm, or larger) and comprising, for example, elemental-semiconductor materials (e.g., silicon (Si) or germanium (Ge)) or compound-semiconductor materials (e.g., silicon germanium (SiGe) or gallium arsenide (GaAs)). Additionally, other substrates include, for example, dielectric materials such as quartz or sapphire (onto which semiconductor materials may be applied).

Each frequency generated by the RF generator 118 may be selected for a specific purpose in the semiconductor device fabrication process. In the example of FIG. 1, with RF powers provided at 2 MHz, 27 MHz, and 60 MHz, the 2 MHz RF power provides ion energy control, and the 27 MHz and 60 MHz powers provide control of the plasma density and the dissociation patterns of the chemistry. This configuration, where each RF power may be turned on or off, enables certain processes that use ultra-low ion energy on the substrates or wafers, and certain processes (e.g., soft etch for low-k materials) where the ion energy has to be low (e.g., under 700 or 200 eV).

In another embodiment, a 60 MHz RF power is used on the top electrode 104 to get ultra-low energies and very high density. This configuration allows chamber cleaning with high-density plasma when the substrate 106 is not in the vacuum chamber 100 while minimizing sputtering on the electrostatic chuck (ESC) surface. The ESC surface is exposed when the substrate 106 is not present, and any ion energy on the surface should be avoided, which is why the bottom two MHz and 27 MHz power supplies ray be off during cleaning.

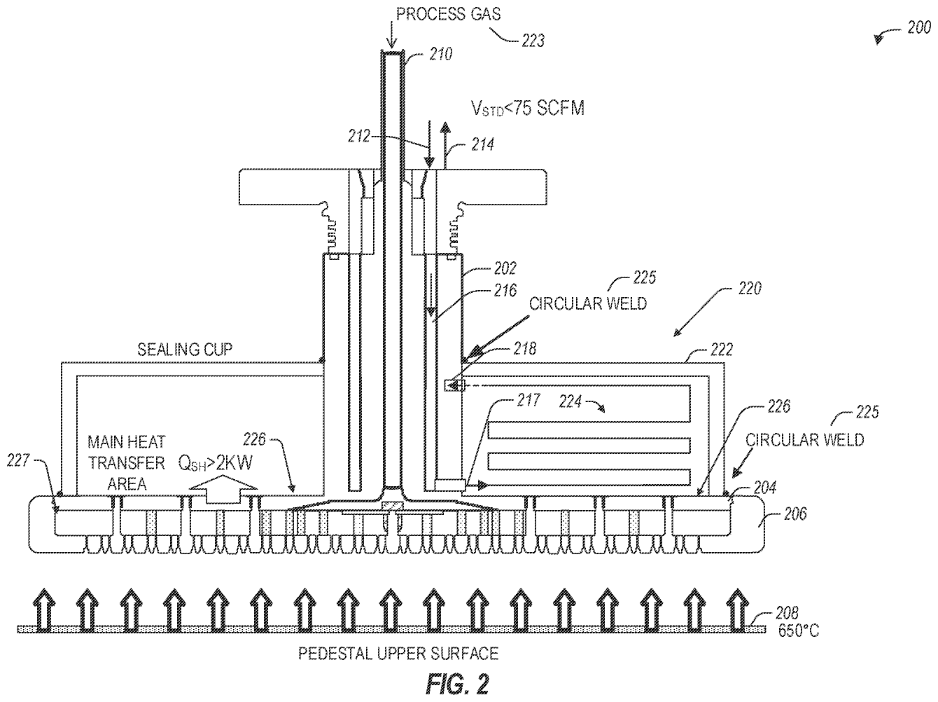

In some aspects, the vacuum chamber 100 includes at least one process gas delivery passageway 134 (through stem 107) to deliver process gases used in CVD or etching via the showerhead 105. The showerhead 105 may include a CHTE 130 configured to include heat transfer structures and to perform functionalities discussed herein. In some aspects, a controller (e.g., a mass flow controller or another controller circuitry) 136 can be coupled to one or more temperature sensors within the showerhead 105 and may control flow rate of a cooling gas (e.g., cooling gas such as CDA from a cooling gas source 140) via the valve 138 and a plurality of cooling gas passageways through the showerhead stem 107 (e.g., inlet passageways 142 and outlet passageways 144 that are used to enable circulation of the cooling gas within the CHTE 130). Various configurations of the CHTE 130 as well as the cooling gas passageways 142 and 144 are discussed herein in connection with FIG. 2-FIG. 13.

FIG. 2 illustrates a temperature-controlled showerhead 200 using a CHTE implementing gas cooling techniques discussed herein, according to some embodiments. Referring to FIG. 2, showerhead 200 can include a stem 202, a face plate 206, and a back plate 204. The stem 202 can include at least one process gas delivery passageway 210 to deliver process gases 223 inside the process gas plenum 227 located above the pedestal upper surface 208.

In some aspects, the showerhead 200 includes a CHTE 220 configured to perform one or more of the showerhead cooling functionalities discussed herein. The showerhead 200 further includes a plurality of inlet cooling gas passageways 212 and a plurality of outlet cooling gas passageways 214 configured to, respectively, deliver and remove cooling gas for thermal control of the showerhead 200 using inlet/outlet paths within the CHTE 220.

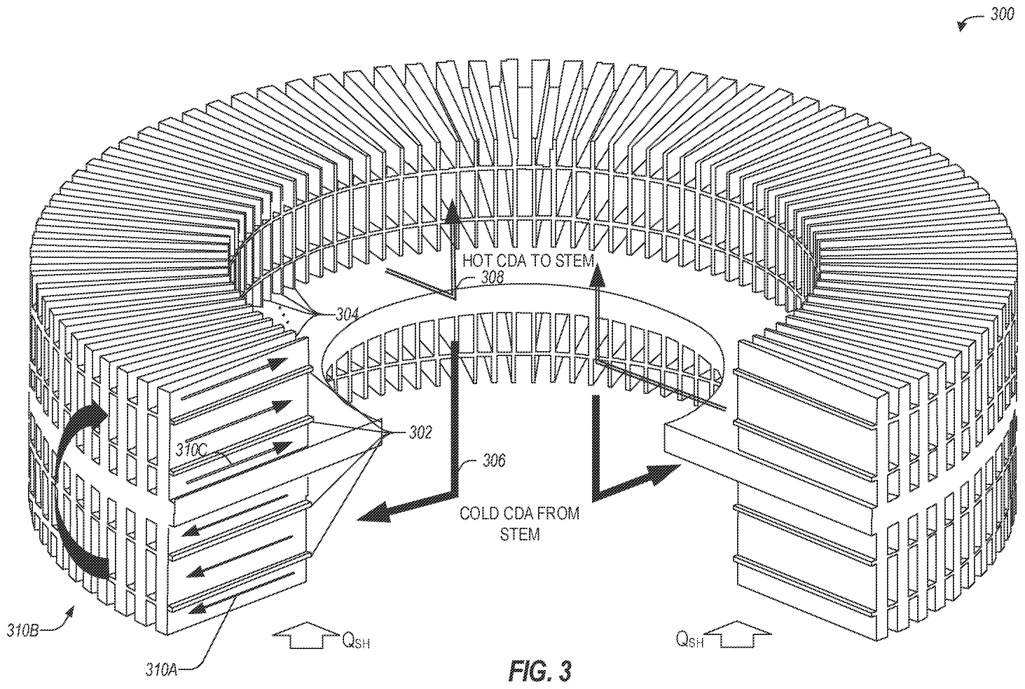

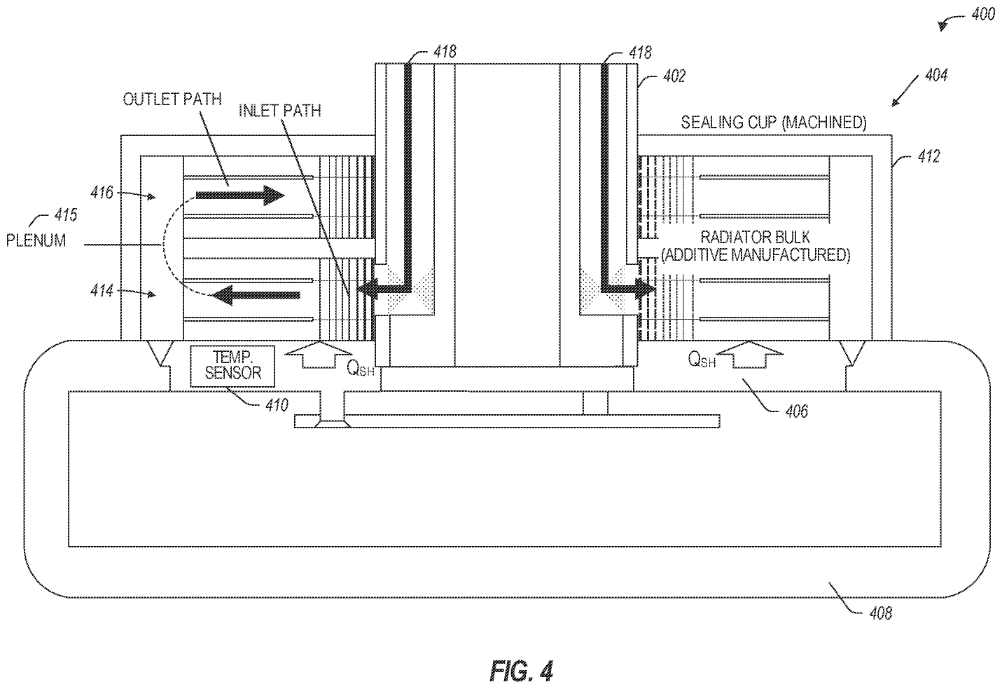

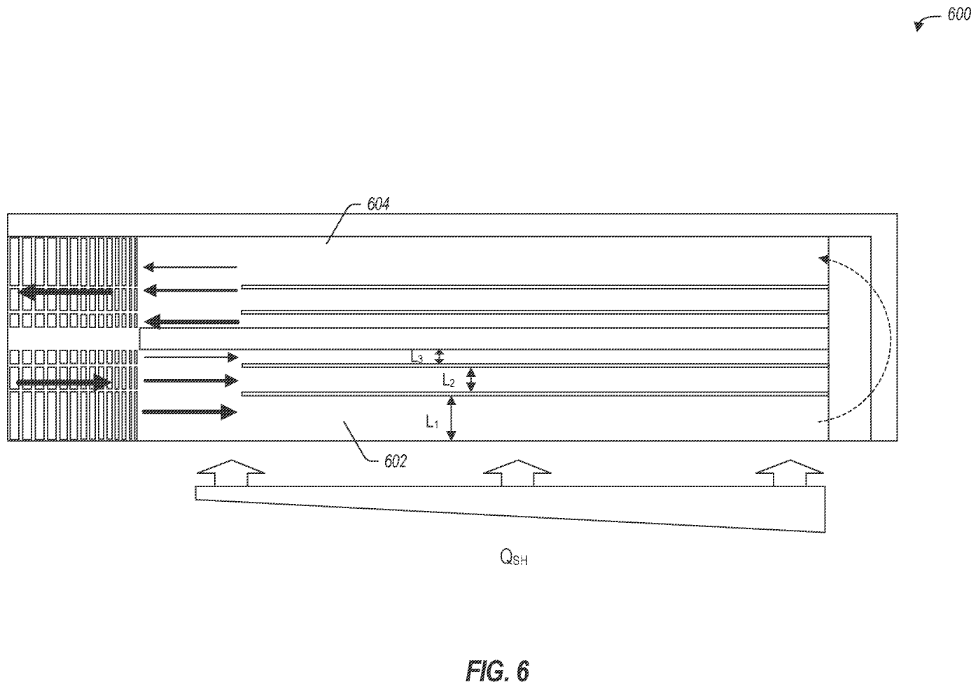

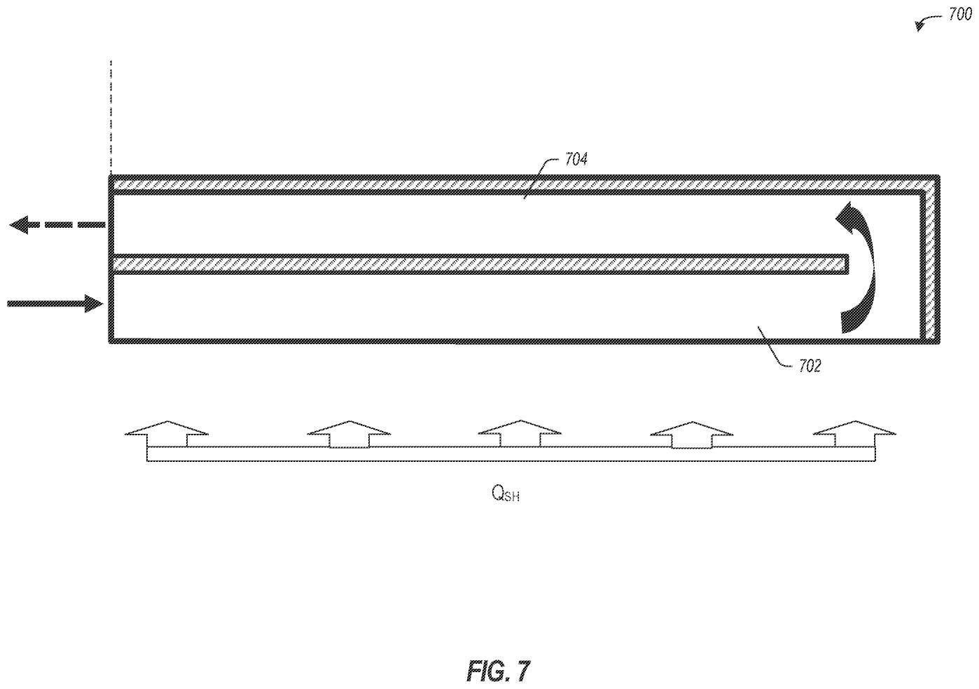

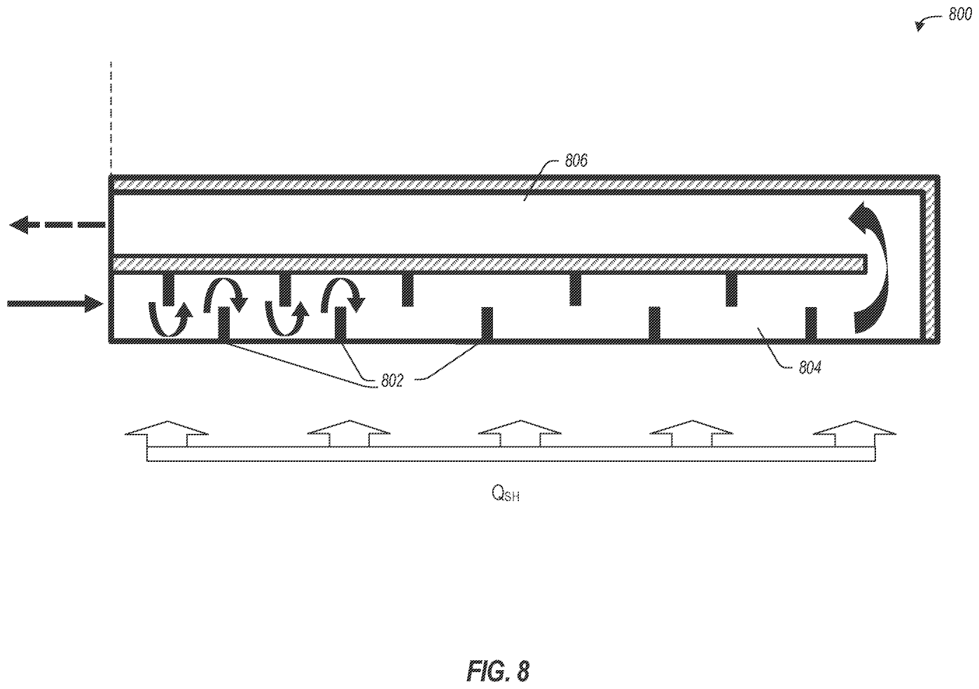

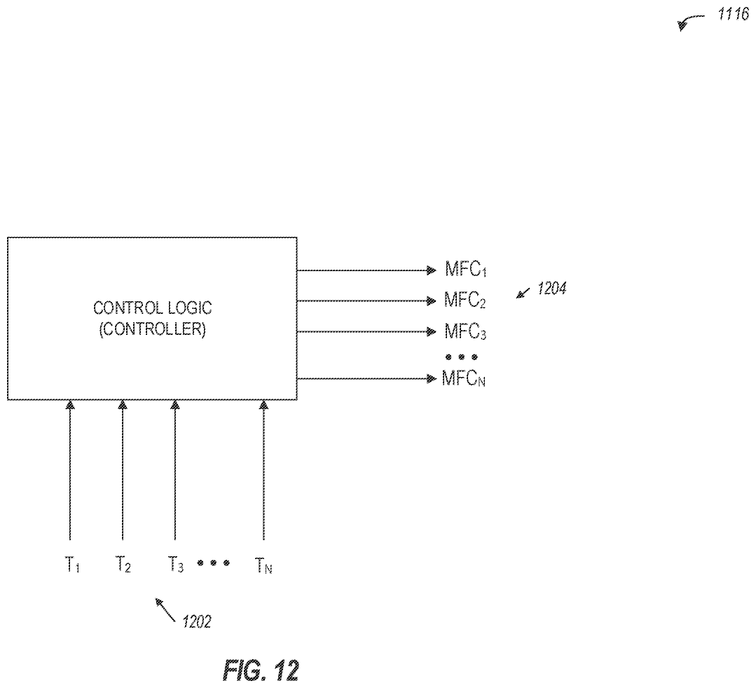

In an example embodiment, cooling gas (e.g., CDA) is delivered to the CHTE 220 via an inlet cooling gas passageway 216 of the of the plurality of inlet cooling gas passageways 212. The cooling gas 224 may enter the CHTE 220 via a first opening 217 (in the stem 202) associated with an inlet path and may exit the CHTE 220 via a second opening 218 (in stem 202) associated with an outlet path. Various configurations of the inlet and outlet paths of the CHTE 220 are illustrated in greater detail in FIG. 3, FIG. 4, FIG. 6, FIG. 7, FIG. 8, and FIG. 13.

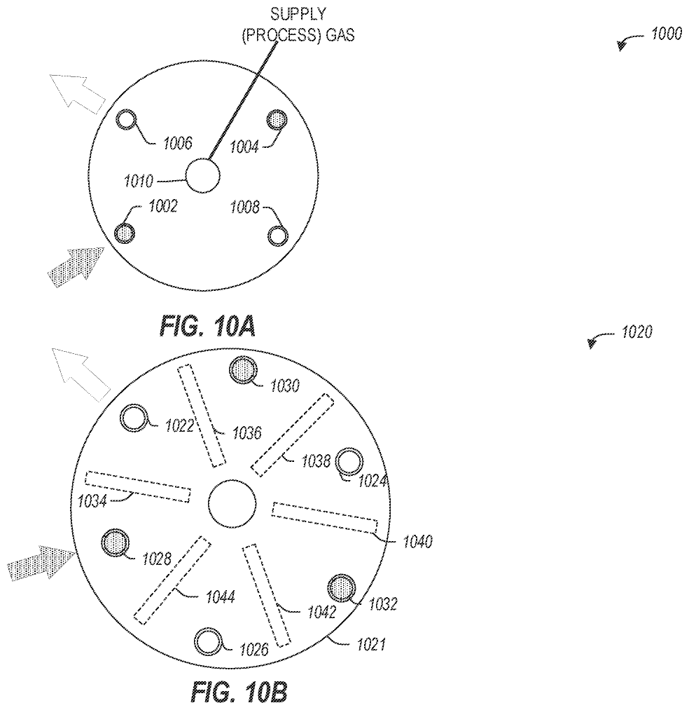

Even though FIG. 2 illustrates only two openings in the stem 202 accommodating delivery and removal of cooling gas within the CHTE 220, the disclosure is not limited in this regard and multiple inlet cooling gas passageways 212 and multiple outlet cooling gas passageways 214 within the stem 202 can have corresponding openings located on the stem 202 (and coupled to corresponding inlet and outlet paths within the CHTE 220). In some aspects, one or more of the multiple inlet paths coupled to the inlet cooling gas passageways 212 can be proximate to (i.e., the cooling gas such as CDA may pass over) a surface area 226 of the back plate 204. In this regard, by regulating a rate of flow of the cooling gas through the inlet paths within the CHTE 220, cooling of the surface area 226 of the back plate 204 (which can be the main heat transfer area of the showerhead 200) can be modulated and controlled (e.g., as illustrated in greater detail in FIG. 11), which may result in showerhead heat dissipation Q_{SH} of 2 kW or more from the face plate 206.

In some aspects, the CHTE 220 can include a sealing cup 222, which can cover the inlet and outlet paths formed by various heat transfer elements inside the CHTE 220, isolating CHTE 220 from process gases inside the chamber. To improve isolation from process gases and the reactive environment inside the chamber, the sealing cup 222 is welded onto the stem 202 and the back plate 204 using circular welds 225. In some aspects, the CHTE 220 can be manufactured (e.g., 3D printed) as part of the stem 202 and including the sealing cup 222.

FIG. 3 illustrates a diagram of a CHTE 300 implementing gas cooling techniques discussed herein, according to some embodiments. Referring to FIG. 3, CHTE 300 includes an arrangement of fins 302 (parallel to an exit plane of showerhead 200 such as the plane of the face plate 206) and fins 304 (perpendicular to the exit plane of showerhead 200) forming a plurality of channels 310B. As illustrated in FIG. 3, cold cooling gas 306 (e.g., called CDA) delivered from the stem via input cooling gas passageway (e.g., via the first opening 217) passes through inlet paths 310A which are located in proximity to the showerhead back plate 204 (which is the main heat transfer area). The hot cooling gas 308 leaves the CHTE 300 via outlet paths 310C (e.g., via the second opening 218).

While a CHTE 300 is illustrated in FIG. 3 with a specific implementation of a heat transfer matrix with specific arrangement of heat transfer structures, the disclosure is not limited in this regard and other arrangements of heat transfer structures within the CHTE can be used as well (e.g., as illustrated in FIG. 6, FIG. 7, FIG. 8, and FIG. 13).

FIG. 4 is a cross-sectional diagram of a temperature-controlled showerhead 400 using a CHTE 404 implementing gas cooling techniques discussed herein, according to some embodiments. Referring to FIG. 4, showerhead 400 includes a stem 40, a back plate 406, a face plate 408, and a CHTE 404 placed at least partially on the back plate 406.

The CHTE 404 is enclosed by a sealing cup 412 which can be machined during a manufacturing process of the showerhead 400. As illustrated in FIG. 4, the stem 402 includes multiple inlet cooling gas passageways 418 (corresponding multiple outlet cooling gas passageways are coupled to the outlet paths of the CHTE 404 but are not visible in FIG. 4).

The CHTE 404 includes multiple machine-patterned plates within the plenum 415, forming at least one inlet path 414 for receiving cooling gas via the passageways 418 and at least one outlet path 416 for removing the hot cooling gas after heat exchange with the back plate surface.

In some aspects, the back plate 406 can include one or more temperature sensors, such as temperature sensor 410. The temperature sensor 410 can be configured to periodically sense and report the temperature of the back plate 406 to a controller (e.g., as illustrated in connection with the system of FIG. 11). In an example embodiment, the controller can be configured to change the rate of flow of the cooling gas (e.g., the pressure of the CDA) supplied via the inlet cooling gas passageways 418 based on the temperature obtained by the temperature sensor 410. Even though FIG. 4 illustrates the temperature sensor 410 is illustrated in FIG. 4 as located within the back plate 406, the disclosure is not limited in this regard and the temperature sensor 410 (or multiple temperature sensors) may be located within other parts of the showerhead 400 (e.g., the temperature sensor(s) may be within the face plate 408 or other parts of the showerhead).

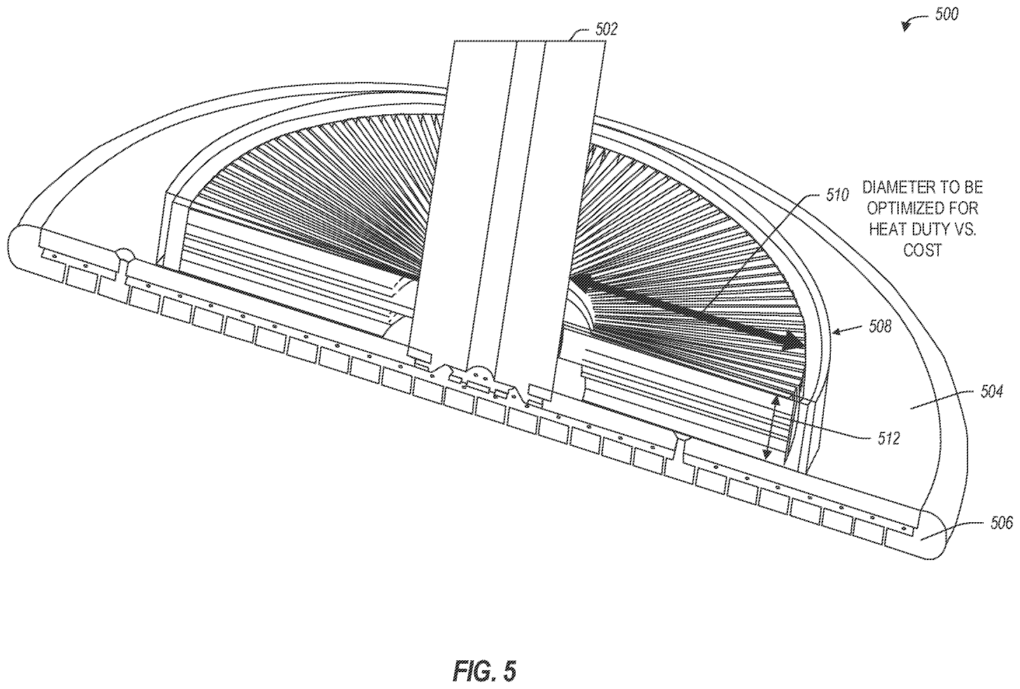

In an example embodiment, various dimensions of heat transfer structures of the CHTE can be optimized (e.g., as illustrated in FIG. 5) based on desired heat dissipation, cost of manufacturing, etc. FIG. 5 is another diagram of a temperature-controlled showerhead 500 using a CHTE implementing gas cooling techniques discussed herein, according to some embodiments. Referring to FIG. 5, showerhead 500 includes a stem 502, a back plate 504, a face plate 506, and a CHTE 508 mounted on top of the back plate 504. In an example embodiment, the diameter 510 and the height 512 of the CHTE 508 can be configured based on heat dissipation requirements, manufacturing costs, and other considerations.

FIG. 6 is a diagram illustrating a cross-sectional view of inlet and outlet paths of CHTE 600 implementing gas-based cooling techniques discussed herein, according to some embodiments. Referring to FIG. 6, CHTE 600 includes heat transfer structures such as multiple stacked machined plates, forming multiple inlet paths 602 and multiple outlet paths 604. As illustrated in FIG. 6, the dimensions (e.g., heights L1, L2, and L3) of the individual inlet and outlet paths 602, 604 can be configured based on beat dissipation requirements, manufacturing costs, and other considerations.

FIG. 7 is a diagram illustrating a cross-sectional view of an inlet path and an outlet path of a CHTE 700 implementing gas-based cooling techniques discussed herein, according to some embodiments. Referring to FIG. 7, CHTE 700 includes heat transfer structures including at least one thermally-conductive plate with increased surface area, forming at least one inlet path 702 and at least one outlet path 704. As illustrated in FIG. 7, as cooling gas passes through the inlet path 702, which is in direct contact with the back plate of the showerhead, heat dissipation from the back plate takes place as heat is absorbed by the cooling gas.

FIG. 8 is another diagram illustrating a cross-sectional view of an inlet path and an outlet path of a CHTE 800 implementing gas-based cooling techniques discussed herein with the inlet path including flow-impingement devices, according to some embodiments. Referring to FIG. 8, CHTE 800 includes heat transfer structures such as at least one machined plate, forming at least one inlet path 804 and at least one outlet path 806. As illustrated in FIG. 8, as cooling gas passes through the inlet path 804, which is in direct contact with the back plate of the showerhead, heat dissipation from the back plate takes place as heat is absorbed by the cooling gas. In an example embodiment, the inlet path 804 may include one or more flow impingement devices to further increase the surface area within the inlet path 804 and improve (e.g., increase) the heat absorption by the cooling gas. In an example embodiment, the flow impingement devices can include vertical barriers 802, which may be orthogonal to the back plate surface the CHTE 800 is mounted on. In other embodiments, such as illustrated in FIG. 13, the flow impingement devices can include nozzles of varying width or other varying nozzle geometry characteristics. Other types of flow impingement devices may also be used to restrict or enhance the flow of cooling gas within the CHTE.

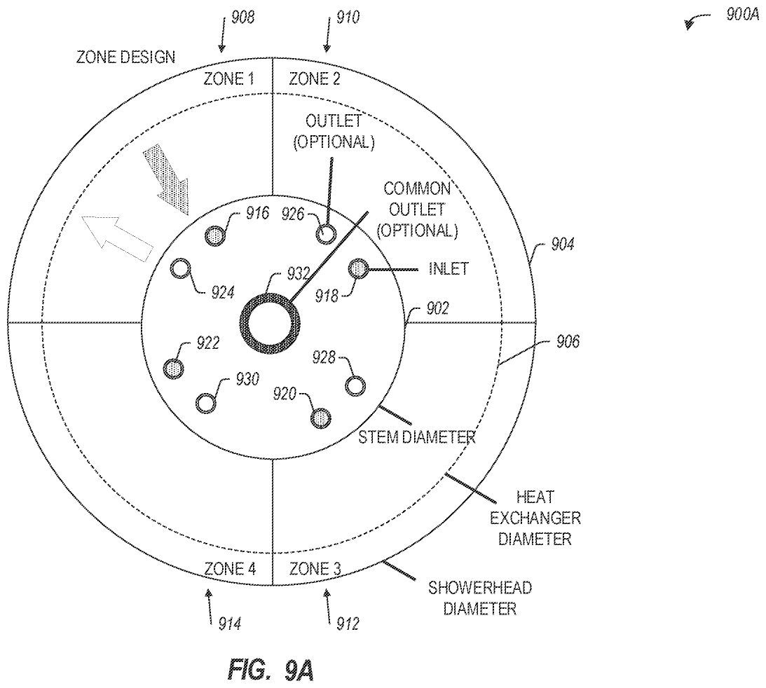

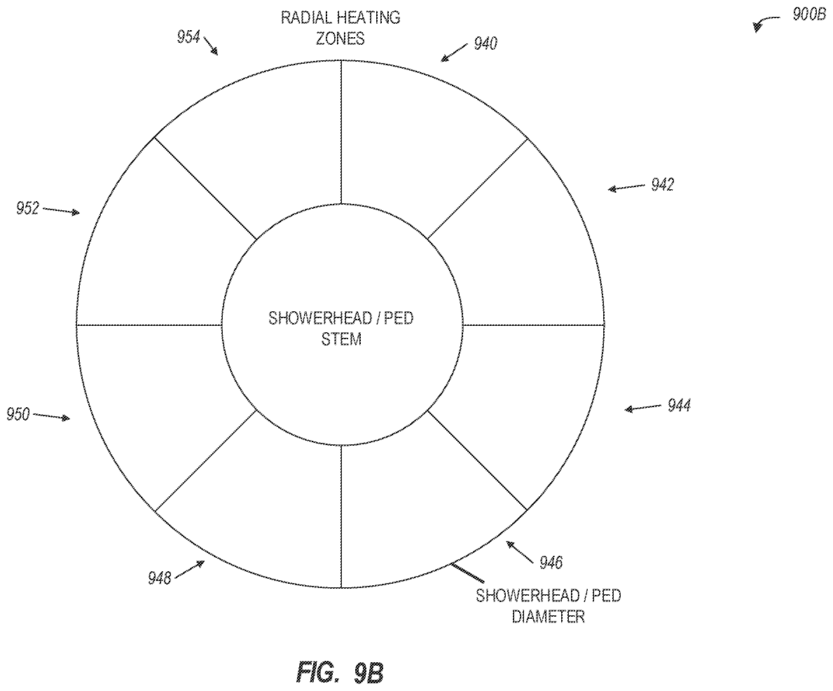

FIG. 9A is a diagram of a top view 900A of a temperature-controlled showerhead 904 using a CHTE 906 implementing gas cooling techniques associated with multiple inlet and outlet cooling gas passageways, according to some embodiments. Referring to FIG. 9A, the top view 900A illustrates multiple inlet cooling gas passageways (e.g., 916, 918, 920, and 922) and multiple outlet cooling gas passageways (e.g., 924, 926, 928, and 930) through the stem 902. In an example embodiment, the CHTE 906 is mounted on a back plate of the showerhead 904 and is configured to include multiple inlet and outlet paths to separately manage thermal dissipation within multiple heating zones of the showerhead back plate. For example and as illustrated in FIG. 9A, the back plate of showerhead 904 is divided into heating zones 908, 910, 912, and 914 and corresponding cooling gas passageways are used to independently manage heat dissipation within each of the heating zones.

More specifically, inlet cooling gas passageway 916 may be used to deliver cooling gas (e.g., CDA or other cooling gases) within a portion of the CHTE 906 placed over the heating zone 908, while outlet cooling gas passageway 924 is used to remove the heated cooling gas associated with the heating zone 908. Similarly, inlet cooling gas passageway 918 may be used to deliver cooling gas within a portion of the CHTE 906 placed over the heating zone 910, while outlet cooling gas passageway 926 is used to remove the heated cooling gas associated with the heating zone 910. Inlet cooling gas passageway 920 may be used to deliver cooling gas within a portion of the CHTE 906 placed over the heating zone 912, while outlet cooling gas passageway 928 is used to remove the heated cooling gas associated with the heating zone 912. Inlet cooling gas passageway 922 may be used to deliver cooling gas within a portion of the CHTE 906 placed over the heating zone 914, while outlet cooling gas passageway 930 is used to remove the heated cooling gas associated with heating zone 914.

In an example embodiment, a common outlet cooling gas passageway 932 may be used in place of the individual outlet cooling gas passageways 924, 926, 928, and 930.

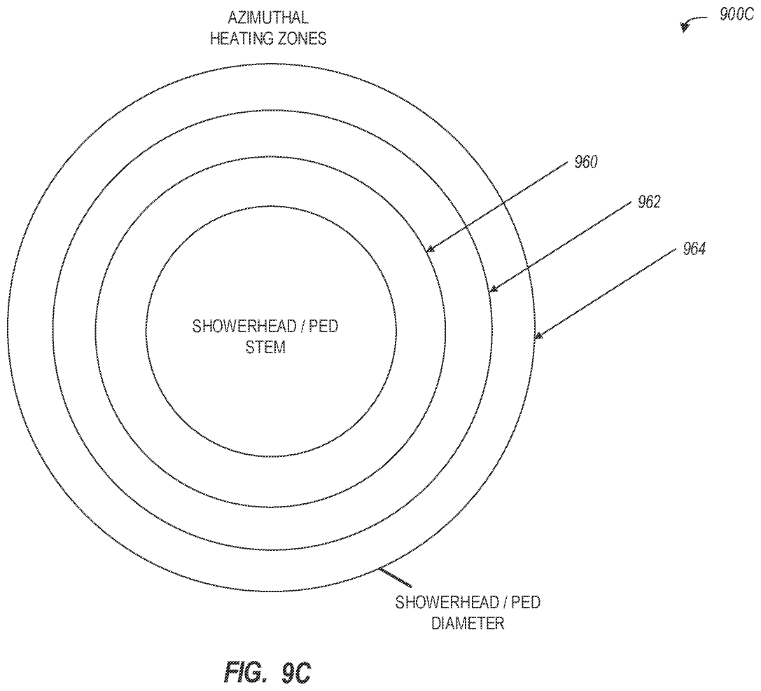

Even though FIG. 9A illustrates four radial heating zones, the disclosure is not limited in this regard and other configurations of heating zones may be used, as illustrated in FIG. 9B and FIG. 9C. Additionally, different configurations of the inlet and outlet cooling gas passageways through the stem are illustrated in connection with FIG. 10A and FIG. 10B.

FIG. 9B and FIG. 9C illustrate different configurations of heating zones, which can be used by the temperature-controlled showerhead of FIG. 9A, according to some embodiments. Referring to FIG. 9B, the showerhead top view 900B illustrates that the back plate may be separated into multiple radial heating zones, including heating zones 940, 942, 944, 946, 948, 950, 952, and 954. Referring to FIG. 9C, the showerhead top view 900C illustrates that the back plate may be separated into multiple azimuthal heating zones, including heating zones 960, 962, and 964. In this regard, corresponding inlet and outlet cooling gas passageways may be configured within the stem so that the rate of flow of cooling gas can be configured and regulated individually for each of the radial and azimuthal heating zones.

FIG. 10A and FIG. 10B illustrate different configurations of inlet and outlet cooling gas passageways within a stem of a temperature-controlled showerhead, according to some embodiments. Referring to FIG. 10A, the showerhead top view 1000 illustrates a stem with at least one process gas delivery passageway 1010 and a pair of inlet cooling gas passageways 1002 and 1004 located across from each other and at equal distances from the at least one process gas delivery passageway 1010. The showerhead top view 1000 further illustrates that the stem includes a pair of outlet cooling gas passageways 1006 and 1008 placed across from each other and also at equal distances from the at least one process gas delivery passageway 1010.

Referring to FIG. 1013, the showerhead top view 1020 illustrates multiple inlet cooling gas passageways 1028, 1030, and 1032, as well as multiple outlet cooling gas passageways 1022, 1024, and 1026 passing through the showerhead stem 1021. In an example embodiment, the inlet and outlet cooling gas passageways can be arranged along the periphery of the stem 1021, with inlet and outlet passageways alternating and being at equal distances from the center process gas delivery passageway. In an example embodiment and as illustrated in FIG. 10B, the stem 1021 can include isolation devices 1034, 1036, 1038, 1040, 1042, and 1044 placed between the inlet and outlet cooling gas passageways to improve thermal efficiency and reduce the cross-transfer of heat between the inlet and outlet passageways. The isolation devices 1034, 1036, 1038, 1040, 1042, and 1044 can include isolation membranes, isolation air gaps, thermally-insulating materials, evacuated spaces, or other isolation means.

FIG. 11 illustrates a system 1100 for temperature control of a showerhead during semiconductor device fabrication, according to some embodiments. Referring to FIG. 11, the system 1100 can include a showerhead CHTE 1101 mounted on a showerhead back plate 1102, which can be used in a semiconductor device processing chamber that includes a pedestal 1103 for holding a semiconductor device (e.g., a substrate). The CHTE 1101 includes heat transfer structures forming multiple heat exchangers, such as heat exchangers 1110, 1112, . . . , 1114. Each of the heat exchangers can be configured for heat management of a specific heating zone associated with the back plate 1102 (e.g., as illustrated in FIG. 9A-FIG. 9C). Additionally, each of the heat exchangers 1110, . . . , 1114 can be configured with the corresponding inlet cooling gas passageways 1132 and outlet cooling gas passageways 1134.

In an example embodiment, each of the inlet cooling gas passageways 1132 may be coupled to a corresponding mass flow controller (MFC) 1118, 1120, . . . , 1122 configured to receive a cooling gas such as CDA 1124, 1126, . . . , 1128 respectively, from facilities or a dedicated compressor 1135.

In an example embodiment, each of the outlet cooling gas passageways 1134 may be coupled to a heat exchanger 1130, which may be configured to recover heat removed from the CHTE 1101 via cooling gas released via the outlet cooling gas passageways 1134. In some aspects, the heat exchanger 1130 can receive cold gas 1131 and use the recovered heat to generate hot gas 1133. In other aspects, hot CDA received via the outlet cooling gas passageways 1134 may be released into the atmosphere. Cooling the existing coolant improves safety and facilitates safe disposal (e.g., by venting into the atmosphere).

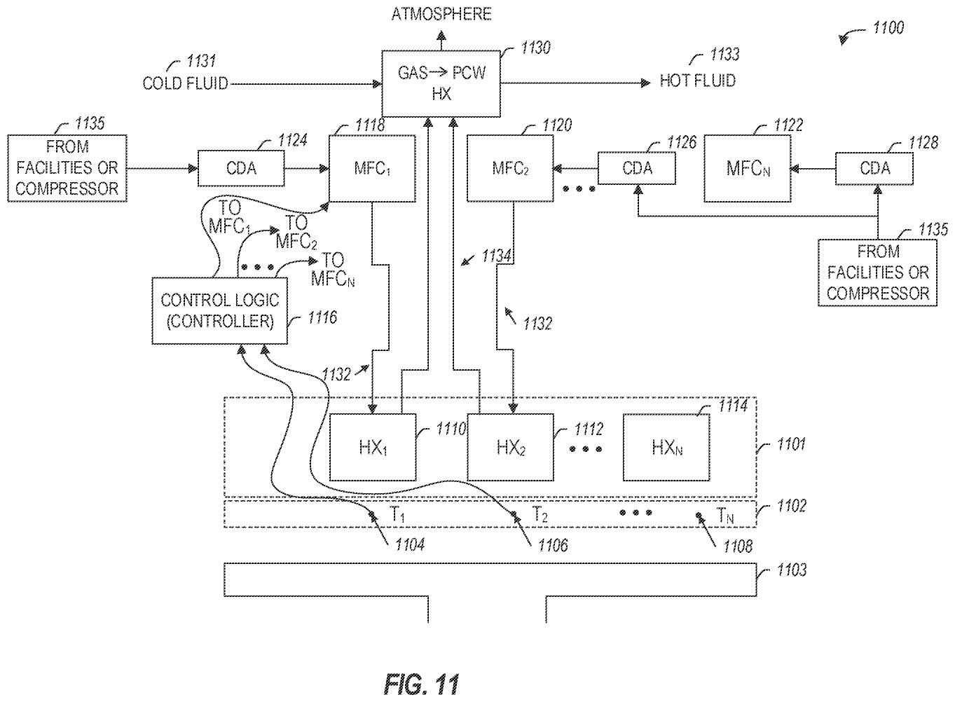

The system 1100 further includes a controller 1116 coupled to the MFCs as well as a plurality of temperature sensors. FIG. 12 is a block diagram of the controller 1116, which can be used to control the rate of flow of cooling gas in the system of FIG. 11, according to some embodiments. Controller 1116 is coupled to a plurality of temperature sensors 1202 and a plurality of MFCs 1204, where the rate of flow for each of the MFCs 1204 may be adjusted/regulated based on temperature from a corresponding temperature sensor of the plurality of temperature sensors 1202.

More specifically and in reference to FIG. 11, controller 1116 may be configured to periodically obtain temperature readings from temperature sensors 1104, 1106, . . . , 1108 within the showerhead back plate 1102. The temperature sensors 1104, 1106, . . . , 1108 can be placed within corresponding heating zones associated with heat exchangers 1110, . . . , 1114. In operation, controller 1116 obtains the temperature readings from the temperature sensors 1104, 1106, . . . , 1108 for each of the heating zones associated with the corresponding heat exchangers and adjusts a rate of flow of cooling gas via the corresponding MFCs 1118, 1120, . . . , 1122. In this regard, the CHTE 1101 can be configured to modulate heat dissipation individually, for one or more of the configured heating zones.

FIG. 13 is a diagram illustrating a cross-sectional view of an inlet path and an outlet path of a CHTE 1300 implementing gas cooling techniques discussed herein with the inlet path including multiple nozzles as flow-impingement devices forming different heating zones, according to some embodiments. Referring to FIG. 13, the CHTE 1300 includes heat transfer structures such as least one thermally-conductive plate with increased surface area, forming at least one inlet path 1302 and at least one outlet path 1304. As illustrated in FIG. 13, the inlet path 1302 includes a plurality of nozzles 1306, 1308, 1310, 1312, 1314, 1316, and 1318, which are configured as flow-impingement devices of the CHTE 1300.

In an example embodiment, various characteristics of the nozzles (e.g., radius, the slope of nozzle walls, etc.) may be different so that different heat dissipation and cooling may be achieved in connection with different heating zones, such as heating zones 1320, 1322, and 1324. The nozzle radius of nozzles 1306-1312 (associated with heating zone 1320) can be smaller than the nozzle radius of nozzles 1314-1316 (associated with heating zone 1322), which is smaller than the nozzle radius of nozzle 1318 (associated with heating zone 1324). In this regard, since the radius of nozzles 1306-1312 is the smallest, maximum heat dissipation is achieved in connection with heating zone 1320.

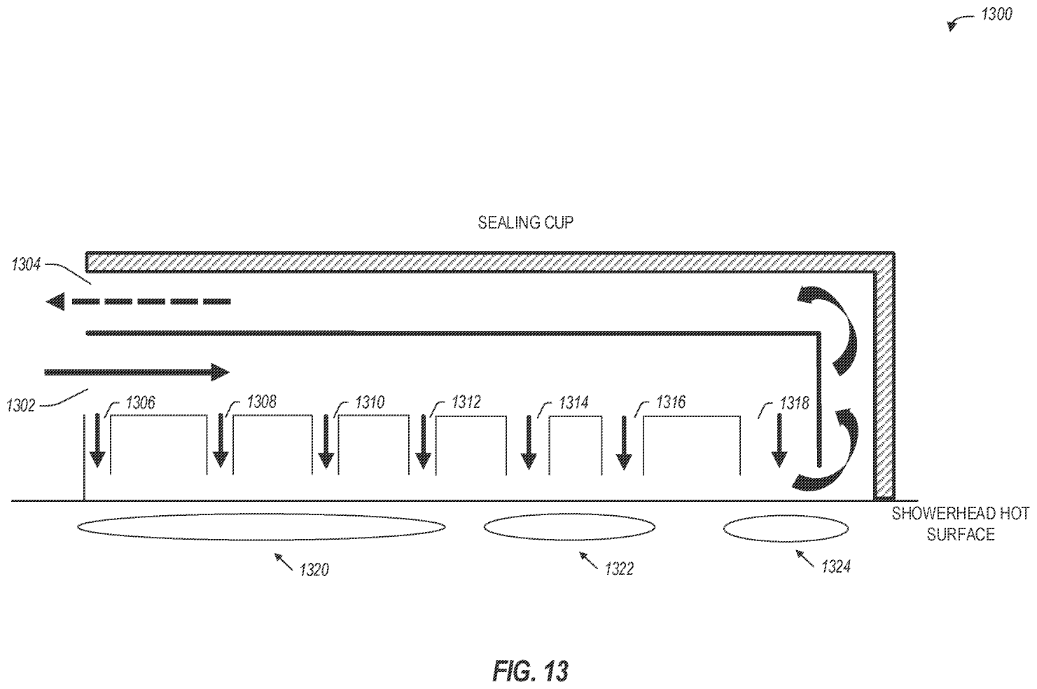

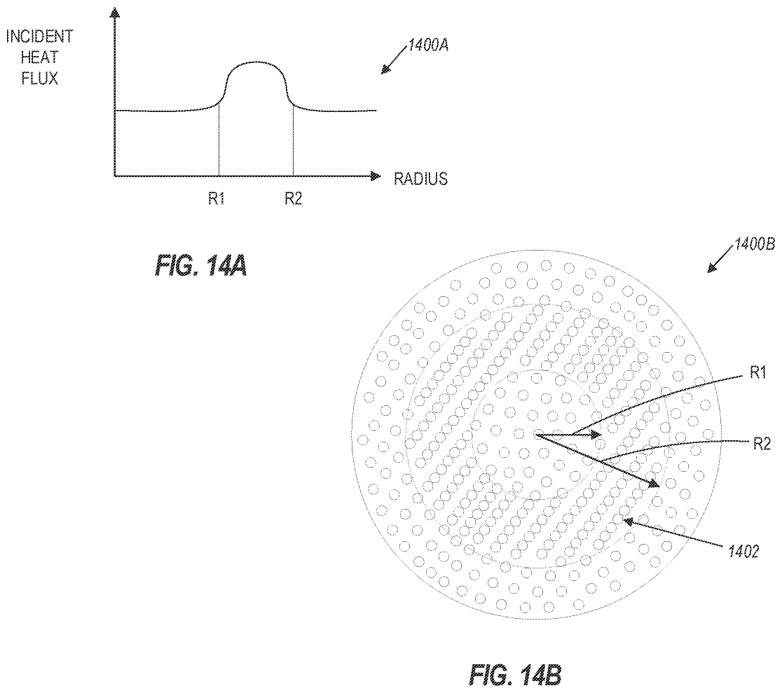

FIG. 14A is a graph 1400A showing heat flux incident upon the face of a showerhead, according to some embodiments. As illustrated in FIG. 14A, the incident heat flux increases within the showerhead space hound between radius R1 and radius R2. FIG. 14B illustrates an array of jet nozzles of a showerhead 1400B having an increased spatial frequency of nozzles in an annular zone 1402 around mid-radius, to increase the cooling effect in the region of the elevated heat flux illustrated in FIG. 14A, according to some embodiments. As illustrated in FIG. 14B, zone 1402 (between radius R1 and radius R2) is associated with increased heat flow density. Consequently, the concentration of jet nozzles within the annular zone 1402 of showerhead 1400B is increased to counteract the elevated heat flux. Other patterns of jet nozzle concentration may also be used based on incident heat flux associated with a showerhead.

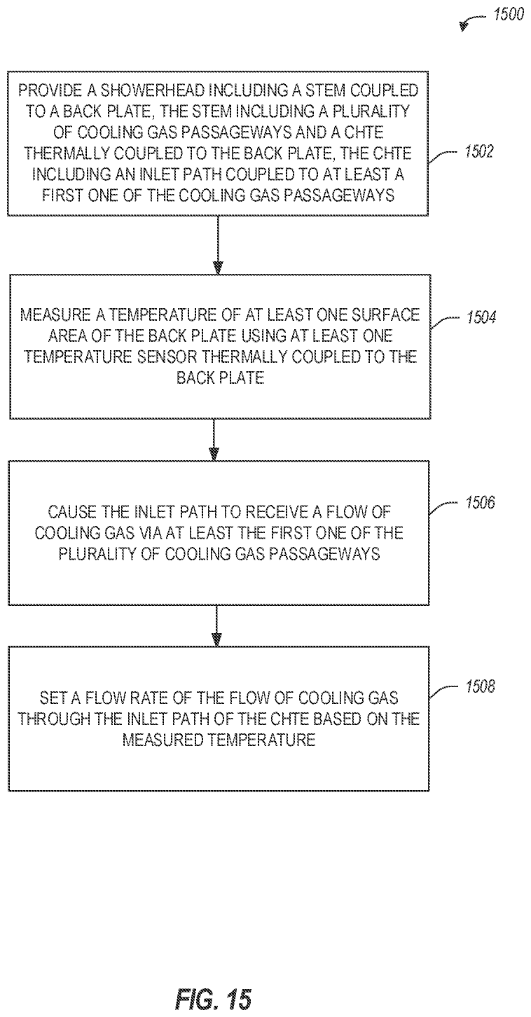

FIG. 15 is a flowchart of a method 1500 for regulating showerhead temperature using gas cooling in semiconductor manufacturing equipment, according to some example embodiments. The method 1500 includes operations 1502, 1504, 1506, and 1508, which may be performed by control logic, such as controller 1116 of FIG. 11 that manages mass flow controllers (MFCs) 1118, . . . , 1122. Referring to FIG. 15, at operation 1502, a showerhead is provided which includes a stem coupled to a back plate (e.g., 1102). The stem includes a plurality of cooling gas passageways (e.g., 1132 and 1134) and a convective heat transfer element (CHTE) (e.g., 1101) thermally coupled to the stem and the back plate. The CHTE includes an inlet path coupled to at least a first one of the plurality of cooling gas passageways, and an outlet path coupled to at least a second one of the plurality of cooling gas passageways. For example, CHTE 1101 includes multiple heat exchangers 1110-1114, with each heat exchanger including at least one inlet path for receiving cooling gas and at least one outlet path for removing heated cooling gas after a heat exchange associated with a heating zone of the back plate 1102.

At operation 1504, a temperature of at least one surface area of the back plate is measured using at least one temperature sensor thermally coupled to the back plate. For example, controller 1116 receives temperature measurements from temperature sensors 1104-1108, with each temperature sensor being associated with a heating zone corresponding to heat exchangers 1110-1114 within the CHTE 1101.

At operation 1506, the controller causes the inlet path to receive a flow of cooling gas via at least the first one of the plurality of cooling gas passageways. For example, controller 1116 causes MFCs 1118-1122 to initiate the flow of cooling gas to corresponding heat exchangers 1110-1114. At operation 1508, a flow rate of the flow of cooling gas through the inlet path of the CHTE may be set based on the measured temperature. For example, controller 1116 uses the temperature measurements received from the temperature sensors 1104-1108 to regulate/adjust a rate of flow of one or more of the MFCs 1118-1122 so that the rate of flow of cooling gas through the heat exchangers 1110-114 can be managed and regulated individually, enabling individual modulation of cooling within the semiconductor device fabrication system 1100.

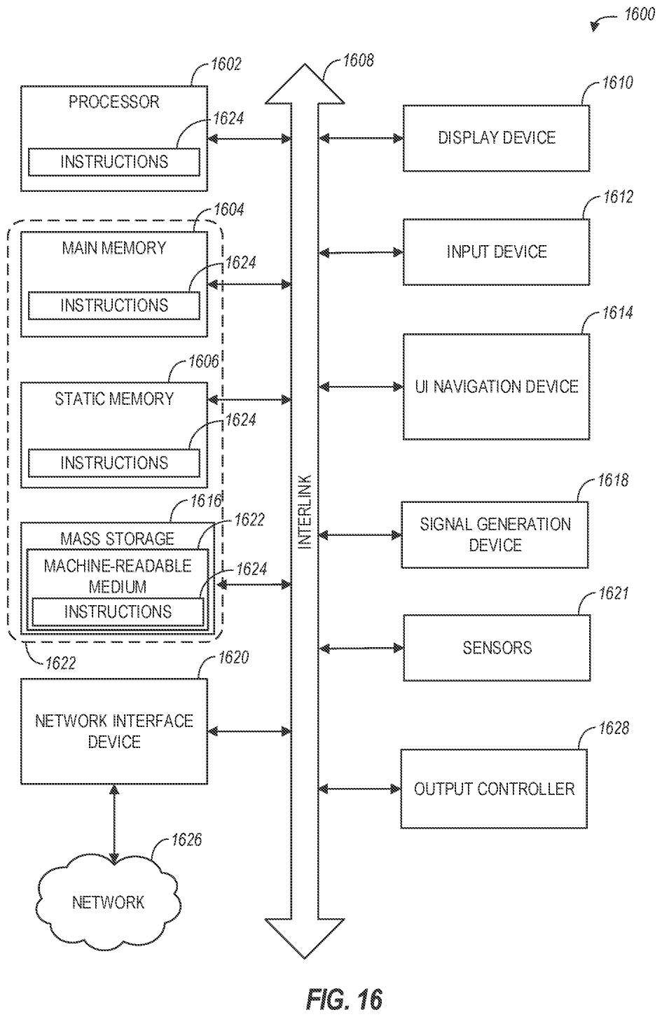

FIG. 16 is a block diagram illustrating an example of a machine 1600 upon which one or more example method embodiments may be implemented, or by which one or more example embodiments may be controlled. In alternative embodiments, the machine 1600 may operate as a standalone device or may be connected (e.g., networked) to other machines. In a networked deployment, the machine 1600 may operate in the capacity of a server machine, a client machine, or both in server-client network environments. In an example, the machine 1600 may act as a peer machine in a peer-to-peer (P2P) (or other distributed) network environment. Further, while only a single machine 1600 is illustrated, the term “machine” shall also be taken to include any collection of machines that individually or jointly execute a set (or multiple sets) of instructions to perform any one or more of the methodologies discussed herein, such as via cloud computing, software as a service (SaaS), or other computer cluster configurations.

Examples, as described herein, may include, or may operate by, logic, a number of components, or mechanisms. Circuitry is a collection of circuits implemented in tangible entities that include hardware (e.g., simple circuits, gates, logic). Circuitry membership may be flexible over time and underlying hardware variability. Circuitries include members that may, alone or in combination, perform specified operations when operating. In an example, the hardware of the circuitry may be immutably designed to carry out a specific operation (e.g., hardwired). In an example, the hardware of the circuitry may include variably connected physical components (e.g., execution units, transistors, simple circuits) including a computer-readable medium physically modified (e.g., magnetically, electrically, by the moveable placement of invariant massed particles) to encode instructions of the specific operation. In connecting the physical components, the underlying electrical properties of a hardware constituent are changed (for example, from an insulator to a conductor or vice versa). The instructions enable embedded hardware (e.g., the execution units or a loading mechanism) to create members of the circuitry in hardware via the variable connections to carry out portions of the specific operation when in operation. Accordingly, the computer-readable medium is communicatively coupled to the other components of the circuitry when the device is operating. In some aspects, any of the physical components may be used in more than one member of more than one circuitry. For example, under operation, execution units may be used in a first circuit of a first circuitry at one point in time and reused by a second circuit in the first circuitry, or by a third circuit in a second circuitry, at a different time.

The machine (e.g., computer system) 1600 may include a hardware processor 1602 (e.g., a central processing unit (CPU), a hardware processor core, a graphics processing unit (GPU), or any combination thereof), a main memory 1604, and a static memory 1606, some or all of which may communicate with each other via an interlink (e.g., bus) 1608. The machine 1600 may further include a display device 1610, an alphanumeric input device 1612 (e.g., a keyboard), and a user interface (UI) navigation device 1614 (e.g., a mouse). In an example, the display device 1610, alphanumeric input device 1612, and UI navigation device 1614 may be a touch screen display. The machine 1600 may additionally include a mass storage device (e.g., drive unit) 1616, a signal generation device 1618 (e.g., a speaker), a network interface device 1620, and one or more sensors 1621, such as a Global Positioning System (GPS) sensor, compass, accelerometer, or another sensor. The machine 1600 may include an output controller 1628, such as a serial (e.g., universal serial bus (USB)), parallel, or other wired or wireless (e.g., infrared (IR), near field communication (NFC)) connection to communicate with or control one or more peripheral devices (e.g., a printer, card reader).

In an example embodiment, the hardware processor 1602 may perform the functionalities of the controller 1116 or any control logic discussed hereinabove (e.g., as discussed in connection with at least FIG. 11).

The mass storage device 1616 may include a machine-readable medium 1622 on which is stored one or more sets of data structures or instructions 1624 (e.g., software) embodying or utilized by any one or more of the techniques or functions described herein. The instructions 1624 may also reside, completely or at least partially, within the main memory 1604, within the static memory 1606, or within the hardware processor 1602 during execution thereof by the machine 1600. In an example, one or any combination of the hardware processor 1602, the main memory 1604, the static memory 1606, or the mass storage device 1616 may constitute machine-readable media.

While the machine-readable medium 1622 is illustrated as a single medium, the term “machine-readable medium” may include a single medium or multiple media, (e.g., a centralized or distributed database, and/or associated caches and servers) configured to store the one or more instructions 1624.

The term “machine-readable medium” may include any medium that is capable of storing, encoding, or carrying instructions 1624 for execution by the machine 1600 and that cause the machine 1600 to perform any one or more of the techniques of the present disclosure, or that is capable of storing, encoding, or carrying data structures used by or associated with such instructions 1624. Non-limiting machine-readable medium examples may include solid-state memories and optical and magnetic media. In an example, a massed machine-readable medium comprises a machine-readable medium 1622 with a plurality of particles having invariant (e.g., rest) mass. Accordingly, massed machine-readable media are not transitory propagating signals. Specific examples of massed machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The instructions 1624 may further be transmitted or received over a communications network 1626 using a transmission medium via the network interface device 1620.

Implementation of the preceding techniques may be accomplished through any number of specifications, configurations, or example deployments of hardware and software. It should be understood that the functional units or capabilities described in this specification may have been referred to or labeled as components or modules, in order to more particularly emphasize their implementation independence. Such components may be embodied by any number of software or hardware forms. For example, a component or module may be implemented as a hardware circuit comprising custom very-large-scale integration (VLSI) circuits or gate arrays, off-the-shelf semiconductors such as logic chips, transistors, or other discrete components. A component or module may also be implemented in programmable hardware devices such as field-programmable gate arrays, programmable array logic, programmable logic devices, or the like. Components or modules may also be implemented in software for execution by various types of processors. An identified component or module of executable code may, for instance, comprise one or more physical or logical blocks of computer instructions, which may, for instance, be organized as an object, procedure, or function. Nevertheless, the executables of an identified component or module need not be physically located together but may comprise disparate instructions stored in different locations which, when joined logically together, comprise the component or module and achieve the stated purpose for the component or module.

Indeed, a component or module of executable code may be a single instruction, or many instructions, and may even be distributed over several different code segments, among different programs, and across several memory devices or processing systems. In particular, some aspects of the described process (such as code rewriting and code analysis) may take place on a different processing system (e.g., in a computer in a data center), than that in which the code is deployed (e.g., in a computer embedded in a sensor or robot). Similarly, operational data may be identified and illustrated herein within components or modules and may be embodied in any suitable form and organized within any suitable type of data structure. The operational data may be collected as a single data set or may be distributed over different locations including over different storage devices, and may exist, at least partially, merely as electronic signals on a system or network. The components or modules may be passive or active, including agents operable to perform desired functions.

### ADDITIONAL NOTES & EXAMPLES

Example 1 is a temperature-controlled showerhead assembly, including a stem comprising a plurality of cooling gas passageways and at least one process gas delivery passageway, the at least one process gas delivery passageway entering the stem at a first end and exiting the stem at a second end opposite the first end; a hack plate structurally coupled to the stem at the second end; a face plate thermally coupled to the stem and attached to the back plate, the face plate and the back plate defining a plenum therebetween, and a convective heat transfer element (CHTE) thermally coupled to the stem and the back plate, the CHTE having an internal plenum including an inlet path for receiving a flow of cooling gas via at least a first one of the plurality of cooling gas passageways, and an outlet path for removing the flow of cooling gas from the CHTE via at least a second one of the plurality of cooling gas passageways, the received flow of cooling gas being thermally coupled with a surface of the back plate.

In Example 2, the subject matter of Example 1 includes subject matter where the flow of cooling gas is received via a first opening on the stem connected to the first one of the plurality of cooling gas passageways; and the flow of cooling gas is removed via a second opening on the stem connected to the second one of the plurality of cooling gas passageways.

In Example 3, the subject matter of Example 2 includes subject matter where a sealing cup structure attached to the stem and the back plate via circular welds, forming an airtight enclosure of the CHTE.

In Example 4, the subject matter of Example 3 includes subject matter where the first opening and the second opening are located on a portion of the stem enclosed by the sealing cup.

In Example 5, the subject matter of Examples 1-4 includes subject matter where the CHTE comprises a plurality of stacked heat-conducting plates, forming the inlet path and the outlet path.

In Example 6, the subject matter of Examples 1-5 includes subject matter where the CHTE comprises a plurality of vertical and horizontal fins forming a plurality of channels associated with the inlet path and the outlet path.

In Example 7, the subject matter of Examples 1-6 includes subject matter where the plurality of cooling gas passageways are configured to flow at least one of the following: clean dry air (CDA); argon; helium; nitrogen; and hydrogen.

In Example 8, the subject matter of Examples 1-7 includes subject matter where the inlet path of the CHTE is defined at least partially by the surface of the back plate.

In Example 9, the subject matter of Examples 1-8 includes subject matter where the inlet path is configured to receive the flow of cooling gas via a first subset of the plurality of cooling gas passageways, and the outlet path is configured to remove the flow of cooling gas via a second subset of the plurality of cooling gas passageways.

In Example 10, the subject matter of Example 9 includes subject matter where the first subset and the second subset of the plurality of cooling gas passageways are substantially parallel to the at least one process gas delivery passageway within the stem.

In Example 11, the subject matter of Examples 9-10 includes subject matter where the first subset of the plurality of cooling gas passageways is thermally isolated from the second subset of the plurality of cooling gas passageways via a plurality of isolation membranes within the stem.

In Example 12, the subject matter of Examples 9-11 includes subject matter where the first subset of the plurality of cooling gas passageways is thermally isolated from the second subset of the plurality of cooling gas passageways via a plurality of isolation air gaps within the stem.

Example 13 is a temperature control system for controlling showerhead temperature including a semiconductor device processing chamber comprising a temperature-controlled showerhead, the showerhead comprising: a stem comprising a plurality of cooling gas passageways and at least one process gas delivery passageway, the at least one process gas delivery passageway entering the stem at a first end and exiting the stem at a second end opposite the first end; a back plate structurally coupled to the stem at the second end; a face plate thermally coupled to the stem and attached to the back plate, the face plate and the back plate defining a plenum therebetween; at least one temperature sensor thermally coupled to the back plate and configured to measure a temperature of at least one surface area of the back plate; and a convective heat transfer element (CHTE) thermally coupled to the stem and the back plate, the CHTE having an internal plenum including an inlet path for receiving a flow of cooling gas via at least a first one of the plurality of cooling gas passageways, and an outlet path for removing the flow of cooling gas from the CHTE via at least a second one of the plurality of cooling gas passageways, the received flow of cooling gas being thermally coupled with a surface of the back plate; and a mass flow controller (MFC) coupled to the plurality of cooling gas passageways and the at least one temperature sensor of the showerhead, the MFC configured to set a flow rate of the flow of cooling gas through the inlet path of the CHTE based on the measured temperature.

In Example 14, the subject matter of Example 13 includes subject matter where the at least one temperature sensor is thermally coupled to the face plate.

In Example 15, the subject matter of Examples 13-14 includes subject matter where the at least one temperature sensor is thermally coupled to the stem.

In Example 16, the subject matter of Examples 13-15 includes subject matter where the MFC is configured to: periodically obtain the measured temperature from the at least one temperature sensor, and dynamically adjust the flow rate of the flow of cooling gas based on the measured temperature.

In Example 17, the subject matter of Examples 13-16 includes subject matter where the CHTE comprises a plurality of stacked heat-conducting plates, forming the inlet path and the outlet path.

In Example 18, the subject matter of Examples 13-17 includes subject matter where the CHTE comprises a plurality of vertical and horizontal fins forming a plurality of channels associated with the inlet path and the outlet path.

In Example 19, the subject matter of Examples 13-18 includes subject matter where the CHTE comprises a plurality of flow impingement devices forming the inlet path.

In Example 20, the subject matter of Example 19 includes subject matter where the plurality of flow impingement devices comprises at least a first subset of nozzles and at least a second subset of nozzles forming the inlet path.

In Example 21, the subject matter of Example 20 includes subject matter where the first subset of nozzles is associated with a first nozzle width and the second subset of nozzles is associated with a second nozzle width that is different from the first nozzle width.

In Example 22, the subject matter of Examples 19-21 includes subject matter where the plurality of flow impingement devices comprises a plurality of vertical barriers, the plurality of vertical barriers being substantially orthogonal to the surface area of the back plate.

Example 23 is a temperature control system for controlling showerhead temperature in a semiconductor device processing chamber, the semiconductor device processing chamber comprising a temperature-controlled showerhead, the showerhead comprising: a stem comprising a plurality of cooling gas passageways and at least one process gas delivery passageway, the at least one process gas delivery passageway entering the stem at a first end and exiting the stem at a second end opposite the first end; a back plate structurally coupled to the stem at the second end; a face plate thermally coupled to the stem and attached to the back plate, the face plate and the back plate defining a plenum therebetween, the plenum receiving the process gas via the process gas passageway; a plurality of temperature sensors thermally coupled to the back plate and configured to measure a plurality of temperatures of a corresponding plurality of heating zones of the back plate; and a convective heat transfer element (CHTE) thermally coupled to the stem and the back plate, the CHTE comprising a plurality of inlet paths configured to receive flows of cooling gas via a first subset of the plurality of cooling gas passageways, and a plurality of outlet paths for removing the flows of cooling gas from the CHTE via a second subset of the plurality of cooling gas passageways, the received flows of cooling gas for each of the plurality of inlet paths being thermally coupled with a corresponding heating zone of the plurality of heating zones of the back plate; a mass flow controller (MFC) coupled to the plurality of cooling gas passageways and the plurality of temperature sensors, the MFC configured to set a flow rate for each of the flows of cooling gas through the plurality of inlet paths of the CHTE based on the measured plurality of temperatures; and a cooling system coupled to at least the second subset of the plurality of cooling gas passageways and configured to cool the flows of cooling gas removed from the CHTE.

In Example 24, the subject matter of Example 23 includes subject matter where the plurality of heating zones are configured as azimuthal heating zones in relation to a center of the stem.

In Example 25, the subject matter of Examples 23-24 includes subject matter where the plurality of heating zones are configured as radial heating zones in relation to a center of the stem.

In Example 26, the subject matter of Examples 23-25 includes subject matter where the MFC is configured to periodically obtain the measured plurality of temperatures from the plurality of temperature sensors; and dynamically adjust the flow rate for one or more of the flows of cooling gas through the plurality of inlet paths of the CHTE based on the measured plurality of temperatures.

In Example 27, the subject matter of Examples 23-26 includes subject matter where the CHTE comprises a plurality of stacked heat-conducting plates, forming the plurality of inlet paths and the plurality of outlet paths.

In Example 28, the subject matter of Examples 23-27 includes subject matter where the CHTE comprises a plurality of vertical and horizontal fins forming a plurality of channels associated with the plurality of inlet paths and the plurality of outlet paths.

In Example 29, the subject matter of Examples 23-28 includes subject matter where the CHTE comprises a plurality of flow impingement devices forming the plurality of inlet paths.

Example 30 is a method for regulating showerhead temperature using gas cooling, the method comprising: providing a showerhead including a stem coupled to a back plate, the stem including a plurality of cooling gas passageways and a convective heat transfer element (CHTE) thermally coupled to the stem and the back plate, the CHTE including an inlet path coupled to at least a first one of the plurality of cooling gas passageways, and an outlet path coupled to at least a second one of the plurality of cooling gas passageways; measuring a temperature of at least one surface area of the back plate using at least one temperature sensor thermally coupled to the back plate; causing the inlet path to receive a flow of cooling gas via at least the first one of the plurality of cooling gas passageways; and setting a flow rate of the flow of cooling gas through the inlet path of the CHTE based on the measured temperature.

In Example 31, the subject matter of Example 30 includes, wherein the cooling gas is compressed dry air (CDA) and the method further comprising: providing a mass flow controller coupled to at least the first one of the plurality of cooling gas passageways a gas source configured to generate the CDA.

Example 32 is at least one machine-readable medium including instructions that, when executed by processing circuitry, cause the processing circuitry to perform operations to implement of any of Examples 1-31.

Example 33 is an apparatus comprising means to implement of any of Examples 1-31.

Example 34 is a system to implement of any of Examples 1-31.

Example 35 is a method to implement of any of Examples 1-31.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components for example configurations may be implemented as a combined structure or component. Similarly, structures and functionality presented as a single component may be implemented as separate components. These and other variations, modifications, additions, and improvements fall within the scope of the subject matter herein.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

The claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate embodiment.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

What is claimed is:

1. A temperature-controlled showerhead assembly, comprising:
a stem comprising a plurality of cooling gas passageways and at least one process gas delivery passageway, the at least one process gas delivery passageway entering the stem at a first end and exiting the stem at a second end opposite the first end;
a back plate structurally coupled to the stem at the second end;
a face plate thermally coupled to the stem and attached to the back plate, the face plate and the back plate defining a plenum therebetween; and
a convective heat transfer element (CHTE) thermally coupled to the back plate, the CHTE having an internal plenum including an inlet path for receiving a flow of cooling gas via at least a first one of the plurality of cooling gas passageways, and an outlet path for removing the flow of cooling gas from the CHTE via at least a second one of the plurality of cooling gas passageways, the received flow of cooling gas being thermally coupled with a surface of the back plate.

2. The temperature-controlled showerhead assembly of claim 1, wherein:
the flow of cooling gas is received via a first opening on the stem connected to the first one of the plurality of cooling gas passageways; and
the flow of cooling gas is removed via a second opening on the stem connected to the second one of the plurality of cooling gas passageways.

3. The temperature-controlled showerhead assembly of claim 2, further comprising:
a sealing cup structure attached to the stem and the back plate via circular welds, forming an gastight enclosure of the CHTE.

4. The temperature-controlled showerhead assembly of claim 3, wherein the first opening and the second opening are located on a portion of the stem enclosed by the sealing cup.

5. The temperature-controlled showerhead assembly of claim 1, wherein the CHTE comprises a plurality of stacked heat-conducting plates, forming the inlet path and the outlet path.

6. The temperature-controlled showerhead assembly of claim 1, wherein the CHTE comprises a plurality of fins forming a plurality of channels associated with the inlet path and the outlet path.

7. The temperature-controlled showerhead assembly of claim 1, wherein the plurality of cooling gas passageways are configured to flow at least one of the following:
clean dry air (CDA);
argon;
helium;
nitrogen; and
hydrogen.

8. The temperature-controlled showerhead assembly of claim 1, wherein the inlet path of the CHTE is defined at least partially by the surface of the back plate.

9. The temperature-controlled showerhead assembly of claim 1, wherein the inlet path is configured to receive the flow of cooling gas via a first subset of the plurality of cooling gas passageways, and the outlet path is configured to remove the flow of cooling gas via a second subset of the plurality of cooling gas passageways.

10. A temperature control system for controlling showerhead temperature in a semiconductor device processing chamber, comprising:
a temperature-controlled showerhead in the semiconductor device processing chamber, the showerhead comprising:
a stem comprising a plurality of cooling gas passageways and at least one process gas delivery passageway, the at least one process gas delivery passageway entering the stem at a first end and exiting the stem at a second end opposite the first end;
a back plate structurally coupled to the stem at the second end;
a face plate attached to the, back plate, the face plate and the back plate defining a plenum therebetween;
at least one temperature sensor thermally coupled to the back plate and configured to measure a temperature of at least one surface area of the back plate; and
a convective heat transfer element (CHTE) thermally coupled to the hack plate, the CHTE having an internal plenum including an inlet path for receiving a flow of cooling gas via at least a first one of the plurality of cooling gas passageways, and an outlet path for removing the flow of cooling gas from the CHTE via at least a second one of the plurality of cooling gas passageways, the received flow of cooling gas being thermally coupled with a surface of the back plate; and
a controller coupled to the plurality of cooling gas passageways and the at least one temperature sensor of the showerhead, the controller configured to set a flow rate of the flow of cooling gas through the inlet path of the CHTE based on the measured temperature.

11. The system of claim 10, wherein the controller is configured to:
periodically obtain the measured temperature from the at least one temperature sensor; and
dynamically adjust the flow rate of the cooling gas based on the measured temperature.

12. The system of claim 10, wherein the CHTE comprises a plurality of stacked heat-conducting plates, forming the inlet path and the outlet path.

13. The system of claim 10, wherein the CHTE comprises a plurality of vertical and horizontal fins forming a plurality of channels associated with the inlet path and the outlet path.

14. The system of claim 10, wherein the CHTE comprises a plurality of flow impingement devices forming the inlet path.

15. The system of claim 14, wherein the plurality of flow impingement devices comprises at least a first subset of nozzles forming the inlet path.

16. The system of claim 15, wherein the plurality of flow impingement devices comprises at least a second subset of nozzles, wherein the first subset of nozzles are associated with a first nozzle width and the second subset of nozzles are associated with a second nozzle width that is different from the first nozzle width.

17. The system of claim 14, wherein the plurality of flow impingement devices comprises a plurality of vertical barriers, the plurality of vertical barriers being orthogonal to the surface area of the back plate.

18. A temperature control system for controlling showerhead temperature in a semiconductor device processing chamber, the system comprising:
a temperature-controlled showerhead in the semiconductor device processing chamber, the showerhead comprising:
a stem comprising a plurality of cooling gas passageways and at least one process gas delivery passageway, the at least one process gas delivery passageway entering the stem at a first end and exiting the stem at a second end opposite the first end;
a back plate structurally coupled to the stem at the second end;
a face plate attached to the back plate, the face plate and the back plate defining a plenum therebetween, the plenum receiving the process gas via the at least one process gas delivery passageway;
a plurality of temperature sensors thermally coupled to the back plate or the face plate, and configured to measure a plurality of temperatures of a corresponding plurality of heating zones of the back plate; and
a convective heat transfer element (CHTE) thermally coupled to the back plate, the CHTE comprising a plurality of inlet paths configured to receive flows of cooling gas via a first subset of the plurality of cooling gas passageways, and a plurality of outlet paths for removing the flows of cooling gas from the CHTE via a second subset of the plurality of cooling gas passageways, the received flows of cooling gas for each of the plurality of inlet paths being thermally coupled with a corresponding heating zone of the plurality of heating zones of the back plate;
a controller coupled to the plurality of cooling gas passageways and the plurality of temperature sensors, the controller configured to set a flow rate for each of the flows of cooling gas through the plurality of inlet paths of the CHTE based on the measured plurality of temperatures; and
a cooling system coupled to at least the second subset of the plurality of cooling gas passageways and configured to cool the flows of cooling gas removed from the CHTE.

19. The system of claim 18, wherein the plurality of heating zones are configured as azimuthal heating zones in relation to a center of the stem.

20. The system of claim 18, wherein the plurality of heating zones are configured as radial heating zones in relation to a center of the stem.

21. The system of claim 18, wherein the controller is configured to:
periodically obtain the measured plurality of temperatures from the plurality of temperature sensors; and
dynamically adjust the flow rate for one or more of the flows of cooling gas through the plurality of inlet paths of the CHTE based on the measured plurality of temperatures.

22. The system of claim 18, wherein the CHTE comprises a plurality of stacked heat-conducting plates, forming the plurality of inlet paths and the plurality of outlet paths.

23. The system of claim 18, wherein the CHTE comprises a plurality of vertical and horizontal fins forming a plurality of channels associated with the plurality of inlet paths and the plurality of outlet paths.

24. The system of claim 18, wherein the CHTE comprises a plurality of flow impingement devices forming the plurality of inlet paths.
